(19) United States
(12) Patent Application Publication
(10) Pub. No.: US 2024/0339487 A1
(43) Pub. Date: Oct. 10, 2024

(54) DISPLAY DEVICE

(71) Applicant: Xiamen San'an Optoelectronics Co., Ltd., Fujian (CN)

(72) Inventors: Kechuang LIN, Fujian (CN); Peng LIU, Fujian (CN); Anhe HE, Fujian (CN); Shaohua HUANG, Fujian (CN); Mingchun TSENG, Fujian (CN); Xiaomeng LI, Fujian (CN); Hongwei WANG, Fujian (CN)

(73) Assignee: Xiamen San'an Optoelectronics Co., Ltd., Fujian (CN)

(21) Appl. No.: 18/623,056

(22) Filed: Apr. 1, 2024

(30) Foreign Application Priority Data
Apr. 4, 2023 (CN) 202310348744.1

(51) Int. Cl. H01L 27/15

(52) U.S. Cl. CPC H01L 27/156

(57) ABSTRACT

A display device includes a driving substrate, a plurality of micro light-emitting elements dispersedly disposed on the driving substrate, and a common electrode. A groove is provided on the driving substrate between the micro light-emitting elements. Each of the micro light-emitting elements includes an epitaxial structure layer and a first electrode and a second electrode disposed on opposite sides of the epitaxial structure layer. The common electrode is disposed on the driving substrate, is located between the first electrodes of the micro light-emitting elements, and exposes an upper surface of the first electrode. An insulating layer covers sidewalls of the micro light-emitting elements and extends into the groove to improve reliability of the device.

### CROSS-REFERENCE TO RELATED APPLICATION

This application claims the priority benefit of China application serial no. 202310348744.1, filed on Apr. 4, 2023. The entirety of the above-mentioned patent application is hereby incorporated by reference herein and made a part of this specification.

### BACKGROUND

### Technical Field

The disclosure belongs to the field of semiconductor manufacturing, and in particular, relates to a display device using micro light-emitting diodes as display pixels.

### Description of Related Art

In recent years, light-emitting diodes (LEDs) have been widely used in lighting and other fields due to their unique advantages and properties and have replaced the original conventional lighting sources. With the evolution of technology, micro light-emitting diodes (micro LEDs) have the advantages of low power consumption, high brightness, ultra-high resolution, ultra-high color saturation, fast response speed, low energy consumption, and long service life. Micro light-emitting diodes thus are gradually becoming the light-emitting components in new generation displays. As the size of micro light-emitting diodes shrinks, the manufacturing process becomes more difficult. In particular, how to improve device reliability and reduce production costs has become a topic of concern in the industry.

### SUMMARY

The disclosure provides a solution for improving the mass production of a micro display device and is particularly dedicated to solving product reliability problems and reducing the production costs of the overall solution.

In some embodiments, a display device includes a driving substrate providing driving control, a plurality of micro light-emitting elements acting as display light sources and dispersedly disposed on the driving substrate, and a common electrode providing a current to the micro light-emitting elements. Each of the micro light-emitting elements includes an epitaxial structure layer providing electron hole recombination and a first electrode and a second electrode disposed on opposite sides of the epitaxial structure layer. The common electrode is located between the first electrodes of the plurality of micro light-emitting elements and is configured to be electrically connected to the first electrodes. A groove is provided on the driving substrate between the micro light-emitting elements. An insulating layer covers sidewalls of the micro light-emitting elements and extends into the groove. The insulating layer covers the groove, so device reliability in the ultra-fine distance display field is improved in this way.

Based on the above, due to the design provided by the disclosure, improved reliability is provided by the disclosure, and the prospect of introducing micro display devices into large-scale applications is thus enhanced. To make the aforementioned more comprehensible, several embodiments accompanied with drawings are described in detail as follows.

### BRIEF DESCRIPTION OF THE DRAWINGS

FIG. 1 is a schematic cross-sectional structural view of Embodiment 1 of the disclosure.

FIG. 2 is a schematic structural top view of Embodiment 1 of the disclosure.

FIG. 3 is an enlarged cross-sectional structural view of a groove in Embodiment 1 of the disclosure.

FIG. 4 is a schematic cross-sectional structural view of Embodiment 2 of the disclosure.

FIG. 5 is a schematic cross-sectional structural view of Embodiment 3 of the disclosure.

FIG. 6 is a schematic cross-sectional structural view of Embodiment 4 of the disclosure.

FIG. 7 is a schematic cross-sectional structural view of Embodiment 5 of the disclosure.

FIG. 8 is a schematic cross-sectional structural view of Embodiment 6 of the disclosure.

FIG. 9 is a schematic cross-sectional structural view of Embodiment 7 of the disclosure.

FIG. 10 is a schematic cross-sectional structural view of Embodiment 8 of the disclosure.

FIG. 11 is a schematic cross-sectional structural view of Embodiment 9 of the disclosure.

### DESCRIPTION OF THE EMBODIMENTS

In order to make the objectives, technical solutions, and advantages of the embodiments of the disclosure clearer, description will now be made in detail to clearly and completely present preferred embodiments of the disclosure, examples of which are illustrated in the accompanying drawings. Nevertheless, the disclosed embodiments are merely part of the embodiments of the disclosure, not all the embodiments. The technical features designed in the different embodiments of the disclosure described below can be combined with each other as long as the technical features do not conflict with each other. Based on the embodiments of the disclosure, all other embodiments obtained by a person having ordinary skill in the art without making any inventive effort fall within the scope that the disclosure seeks to protect.

In some embodiments, a display device includes a driving substrate providing driving control, a plurality of micro light-emitting elements acting as display light sources and dispersedly disposed on the driving substrate, and a common electrode providing a current to the micro light-emitting elements. Each of the micro light-emitting elements includes an epitaxial structure layer providing electron hole recombination and a first electrode and a second electrode disposed on opposite sides of the epitaxial structure layer. The common electrode is located between the first electrodes of the micro light-emitting elements. The common electrode is configured to be electrically connected to the first electrode. A groove is provided on the driving substrate between the micro light-emitting elements. An insulating layer covers sidewalls of the micro light-emitting elements and extends into the groove. The groove acts as a current blocking groove, and the insulating layer covers the groove, so device reliability in the ultra-fine distance display field is improved in this way.

In some embodiments, preferably, the insulating layer contacts the groove, and a depth of the groove is greater than 100 nanometers and less than 1,000 nanometers, so a sealing property of the insulating layer is improved in this way.

In some embodiments, preferably, a cross section of the groove is V-shaped or U-shaped, and the insulating layer extends on a smooth sidewall of the groove.

In some embodiments, preferably, a minimum distance between the plurality of micro light-emitting elements is 0.1 microns to 2 microns, so display pixels are increased in this way.

In some embodiments, preferably, the common electrode and the first electrodes are integrally formed. A material of the common electrode includes a transparent conductive material or a metal material, and viewed from a top view, the common electrode is in a shape of a grid. The integrally formed structure refers to using the same material or making the structure at the same time using the same process.

In some embodiments, preferably, at least part of the second electrodes are located between the epitaxial structure layer and the driving substrate, and the micro light-emitting elements are bonded to the driving substrate through the second electrodes, for example, the second electrodes are disposed under the epitaxial structure layers.

In some embodiments, preferably, viewed from a top view, a projected area of each of the second electrodes is 0.5 square micrometers to 10 square micrometers, for example, the projected area of a bonding metal layer in the second electrode is no more than 10 square micrometers. With the trend of miniaturization design of the micro light-emitting elements, a size of the second electrode may also be further reduced.

In some embodiments, preferably, the insulating layer in the groove is V-shaped or U-shaped, and keeping a smooth groove sidewall is beneficial to improving a barrier property of the insulating layer.

In some embodiments, preferably, an isolating trench is provided between the micro light-emitting elements, and the groove is disposed in the isolating trench, for example, the groove is disposed in the middle position of adjacent micro light-emitting elements.

In some embodiments, preferably, viewed from a top view, a projected area of each of the second electrodes is 0.3 to 0.8 times or 0.8 to 1 time a projected area of each of the micro light-emitting elements. The second electrodes are shrunk in some processes, but support reliability may be lowered.

In some embodiments, preferably, the insulating layer is disposed on the driving substrate and at least covers the first electrode of each of the micro light-emitting elements. The common electrode is located on the insulating layer and is disposed on an upper surface of the first electrode.

In some embodiments, preferably, a light transmittance of the common electrode is larger than a light transmittance of the first electrode, so light absorption of the common electrode is lowered in this way.

In some embodiments, preferably, the insulating layer extends from a sidewall of the epitaxial structure layer and a sidewall of the second electrode to a sidewall of the groove in sequence and is an insulating inorganic substance or an insulating organic substance. An angle between the sidewall of the epitaxial structure layer and a horizontal plane is α₁, an angle between the sidewall of the second electrode and the horizontal plane is α₂, and an angle between the sidewall of the groove and the horizontal plane is α₃. α₁, α₂, and α₃ are 30° to 80°, and a difference value between α₁ and α₂ and a difference value between α₂ and α₃ are not greater than 20°. The consistent design of the sidewall of each layer structure is used to achieve a smooth transition of the insulating layer covering the sidewall, and reliability of the insulating layer is improved in this way.

In some embodiments, preferably, the epitaxial structure layer includes a first semiconductor layer, a second semiconductor layer, and an active layer located therebetween. The first semiconductor layer is electrically connected to the first electrode, and the second semiconductor layer is electrically connected to the second electrode. The first electrode is an N-type electrode, and the second electrode is a P-type electrode.

In some embodiments, preferably, the insulating layer fills the groove, and the insulating layer is used to improve reliability of the micro light-emitting elements. Since the common electrode covers the insulating layer, as in this embodiment, the common electrode is not disposed in the groove, so that poor continuity of the common electrode in the groove in a small space is avoided.

In some embodiments, preferably, a metal filling layer is further included. One side of the metal filling layer partially or completely fills the isolating trench. Another side of at least a portion of the metal filling layer covers the micro light-emitting element. The insulating layer and/or the common electrode is disposed between an upper surface of the epitaxial structure layer and the metal filling layer. The metal filling layer is used to form an engagement structure, so device strength is improved in this way.

In some embodiments, preferably, the second electrode of each of the plurality of micro light-emitting elements includes a metal reflective layer, a metal barrier layer, or a metal bonding layer. A material of the metal bonding layer includes gold, tin, a nickel-tin mixture, or a gold-tin mixture. When the metal barrier layer includes tin, the reliability of a display end product may be lowered during use, so it is preferred to adopt the laying approach of the insulating layer provided by this embodiment.

In some embodiments, preferably, the insulating layer extends from a sidewall of the epitaxial structure layer and a sidewall of the metal bonding layer to a sidewall of the groove in sequence. An angle between the sidewall of the epitaxial structure layer and a horizontal plane is α₁, an angle between the sidewall of the metal bonding layer and the horizontal plane is α₂′, and an angle between the sidewall of the groove and the horizontal plane is α₃. α₁, α₂′, and α₃ are 30° to 80°, and a difference value between 1 and α₂′ and a difference value between az′ and α₃ are not greater than 20°, so the angle difference of the sidewalls of the micro light-emitting elements is lowered, and an isolating property of the insulating layer is improved in this way.

In some embodiments, preferably, a distance between the metal bonding layers between two adjacent micro light-emitting elements is 0.1 micron to 2 microns or 2 microns to 5 microns. Under the reliability design of this embodiment, reducing the distance between metal bonding layers to 0.1 microns to 2 microns may increase display pixels, but it is more necessary to improve the reliability of the insulating layer.

In some embodiments, preferably, an edge of the metal bonding layer contacts an opening of the groove. At the contact position thereof, the sidewall of the metal bonding layer and the sidewall of the groove form a continuous surface. A difference value between an inclination angle of the sidewall of the metal bonding layer relative to the horizontal plane and an inclination angle of the sidewall of the groove relative to the horizontal plane is not greater than 20°. In this way, adhesion of the insulating layer is improved, and the insulating layer on the surface of the driving substrate is prevented from turning at a large angle.

In some embodiments, the driving substrate is a metal oxide semiconductor substrate, a silicon-based liquid crystal substrate, or a thin film transistor substrate.

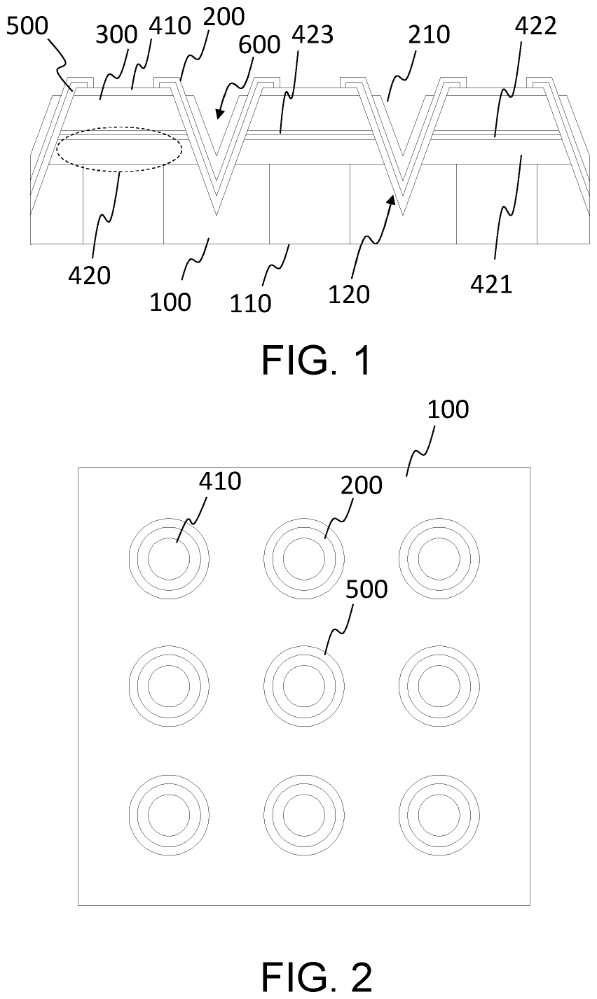

To be specific, with reference to FIG. 1 and FIG. 2, in the first embodiment of the disclosure, a display device includes a driving substrate 100 providing driving control, a plurality of micro light-emitting elements acting as display light sources and dispersedly disposed on the driving substrate 100, and a common electrode 200 providing a current to the micro light-emitting elements. Each micro light-emitting element constitutes a pixel, and the display device may be a micro light-emitting-diode display (micro LED display). The driving substrate 100 is a metal oxide semiconductor substrate, a silicon-based liquid crystal substrate, or a thin film transistor substrate. The cross-section in the figure takes three micro light-emitting elements as an example, but the number of micro light-emitting elements is not limited thereto. A minimum distance between the micro light-emitting elements is 0.1 microns to 2 microns, and in theory, the smaller the distance, the better the display pixels.

Each of the micro light-emitting elements includes an epitaxial structure layer 300 providing electron hole recombination and a first electrode 410 and a second electrode 420 disposed on opposite sides of the epitaxial structure layer 300. The first electrode 410 is located above the epitaxial structure layer, and the second electrode 420 is located below the epitaxial structure layer 300. The epitaxial structure layer 300 includes a first semiconductor layer 310, a second semiconductor layer 320, and an active layer 330 located therebetween. The first semiconductor layer 310 is electrically connected to the first electrode 410, and the second semiconductor layer 320 is electrically connected to the second electrode 420. The first electrode 410 is an N-type electrode, and the second electrode 420 is a P-type electrode. In the driving substrate 100, a conductive contact 110 is also provided, and the conductive contact 110 is electrically connected to the second electrode 420.

The common electrode 200 is located between the first electrodes 410 of adjacent micro light-emitting elements and is configured to be electrically connected to the first electrodes 410. In some embodiments, the common electrode 200 located between the micro light-emitting elements may have a common electrode reflective layer 210 to improve light emission efficiency. An isolating trench 600 is provided between the micro light-emitting elements, extends toward the driving substrate, and forms a groove on the driving substrate. The groove 120 is disposed in the isolating trench 600, for example, the groove 120 is disposed in the middle position of adjacent micro light-emitting elements. The groove 120 is provided on the driving substrate 100 between the micro light-emitting elements. An insulating layer 500 covers sidewalls of the micro light-emitting elements, extends into the groove 120, and covers or fills the groove 120. In some embodiments, each of the micro light-emitting elements has a lens, the lens is disposed above the epitaxial structure layer 300 (not shown), and light exits from the lens.

The driving substrate 100 around the groove is non-conductive. By providing the groove 120 on the driving substrate 100 between adjacent light-emitting elements, the second electrodes 420 of two adjacent light-emitting elements are isolated.

At least part of the second electrodes 420 are located between the epitaxial structure layer 300 and the driving substrate 100, and the micro light-emitting elements are bonded to the driving substrate 100 through the second electrodes 420. Each of the second electrodes 420 may be formed by a single type or multiple types of metals. Viewed from a top view, a projected area of the second electrode 420 is 0.5 square micrometers to 10 square micrometers. For instance, the projected area of the bonding metal layer 421 in the second electrode 420 is no more than 10 square micrometers. It is not ruled out that with the improvement of process progress and the trend of miniaturization design of micro light-emitting elements, the size of the second electrode 420 may be further reduced. The projected area of the second electrode is 0.8 to 1 time the projected area of each of the micro light-emitting elements.

The second electrode 420 includes a metal reflective layer 421, a metal barrier layer 422, or a metal bonding layer 423. A material of the metal bonding layer 421 includes gold, tin, a nickel-tin mixture, or a gold-tin mixture. When the metal barrier layer 422 includes tin, the reliability of the display end product may be lowered during use, so it is preferred to adopt the laying approach of the insulating layer 500 provided by this embodiment. As pixels increase, the distance between micro light-emitting elements gradually shrinks. In this embodiment, a distance between the metal bonding layers 421 between two adjacent micro light-emitting elements is 0.1 microns to 2 microns or 2 microns to 5 microns. Under the reliability design of this embodiment, reducing the distance between the metal bonding layers 421 may increase display pixels.

The insulating layer 500 is disposed on the driving substrate 100 and at least covers the first electrode 410 of each of the micro light-emitting elements. The common electrode 200 is located on the insulating layer 500 and is disposed on an upper surface of the first electrode 410. A light transmittance of the common electrode 200 is larger than a light transmittance of the first electrode 410, so light absorption of the common electrode 200 is lowered in this way.

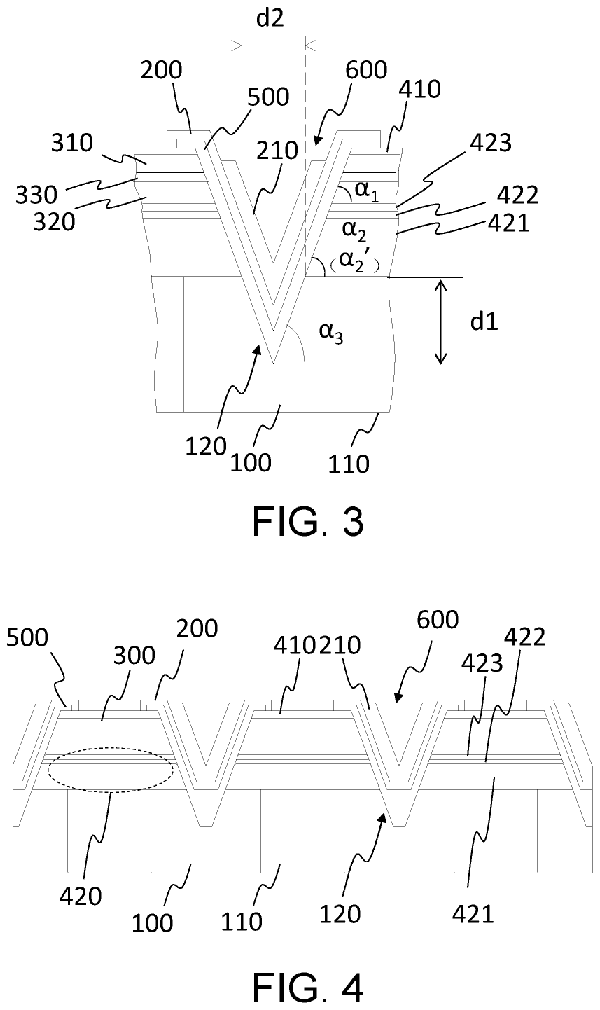

With reference to FIG. 3 together, the insulating layer 500 contacts the groove 120, and a depth d1 of the groove 120 is greater than 100 nanometers and less than 1,000 nanometers, so a sealing property of the insulating layer 500 is improved in this way. A cross section of the groove 120 is V-shaped, and the insulating layer 500 extends on a smooth sidewall of the groove 120. In some embodiments, the insulating layer 500 in the groove 120 is V-shaped, so the sidewall of the groove 120 is kept to be smooth. The insulating layer 500 may also be provided by filling the groove 120.

The insulating layer 500 extends from a sidewall of the epitaxial structure layer 300 and a sidewall of the second electrode 420 to the sidewall of the groove 120 in sequence and is an insulating inorganic substance or an insulating organic substance. An angle between the sidewall of the epitaxial structure layer 300 and a horizontal plane is α₁. Due to the existence of etching deviation, in order to ensure a smooth transition of each layer, α₁ is measured as an angle between a bottom sidewall of the epitaxial structure layer 300 and the horizontal plane. An angle between the sidewall of the second electrode 420 and the horizontal plane is α₂, and α₂ is measured as an angle between a bottom sidewall of the second electrode 420 and the horizontal plane. An angle between the sidewall of the groove 120 and the horizontal plane is α₃, and α₃ is measured as an angle between a top portion of the sidewall of the groove 120 and the horizontal plane. α₁, α₂, and α₃ are 30° to 80°, and the difference value between α₁ and az and the difference value between α₂ and α₃ are not greater than 20°. The consistent design of the sidewall of each layer structure is used to achieve a smooth transition of the insulating layer 500 covering the sidewall, and reliability of the insulating layer 500 is improved in this way.

In some embodiments, the insulating layer 500 extends from the sidewall of the epitaxial structure layer 300 and a sidewall of the metal bonding layer 421 to the sidewall of the groove in sequence. The angle between the sidewall of the epitaxial structure layer 300 and the horizontal plane is α₁. An angle between the sidewall of the metal bonding layer 421 and the horizontal plane is α₁′. An angle between the sidewall of the groove 120 and the horizontal plane is α₃. α₁, α₂′, and α₃ are 30° to 80°, and a difference value between α₁ and α₂′ and a difference value between α₂′ and α₃ are not greater than 20°.

An edge of the metal bonding layer 421 contacts an opening of the groove 120. At the contact position thereof, the sidewall of the metal bonding layer 421 and the sidewall of the groove 120 form a continuous surface. A difference value between an inclination angle of the sidewall of the metal bonding layer 421 relative to the horizontal plane and an inclination angle of the sidewall of the groove 120 relative to the horizontal plane is not greater than 20°. In this way, continuity of the insulating layer 500 is improved, and the insulating layer 500 on the surface of the driving substrate 100 is prevented from turning at a large angle.

A minimum distance between the metal bonding layers 421 of adjacent micro light-emitting elements is d2. In this embodiment, d2 is also the minimum distance of micro light-emitting elements, and d2 is 0.1 microns to 2 microns.

With reference to FIG. 4, in the second embodiment of the disclosure, the cross section of the groove 120 is U-shaped, and the insulating layer 500 extends on the smooth sidewall of the groove 120. The insulating layer 500 in the groove 120 is U-shaped, so the sidewall of the groove 120 is kept to be smooth. The insulating layer 500 may also be provided by filling the groove 120.

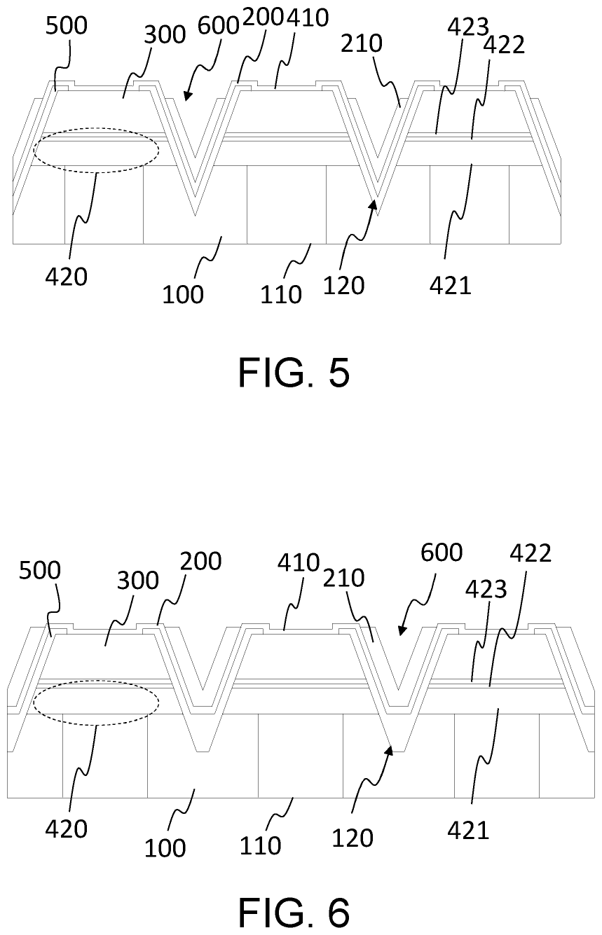

With reference to FIG. 5, in the third embodiment of the disclosure, the common electrode 200 and the first electrodes 410 are integrally formed. A material of the common electrode 200 includes a transparent conductive material or a metal material, and viewed from a top view, the common electrode 200 is in a shape of a grid. The are integrally formed structure refers to using the same material or making the structure at the same time using the same process. One mask design may be reduced, and the common electrode 200 extends from the isolating trench 600 to the surface of the epitaxial structure layer 300.

With reference to FIG. 6, in the fourth embodiment of the disclosure, a height of the common electrode 200 on the side above the epitaxial structure layer is higher than that of the epitaxial structure layer 300, for example, higher than the first semiconductor layer 310. The common electrode 200 may be made of metal. Due to the significantly increased density of light-emitting elements under microLED application conditions, it is difficult to repair the light-emitting elements after abnormalities, so heat dissipation and reliability are key indicators. In this embodiment, by introducing the common electrode 200 from the region between the light-emitting elements to the upper surface of the micro display device, which is higher than the epitaxial structure layer, the overall heat dissipation property of the device is thereby improved.

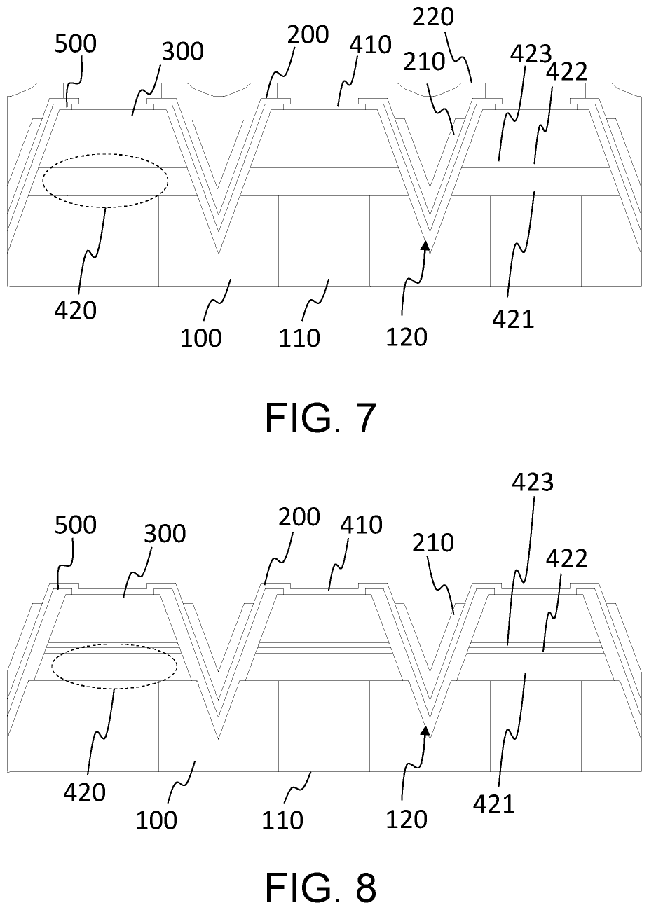

With reference to FIG. 7, in the fifth embodiment of the disclosure, a metal filling layer 220 is further included. The metal filling layer 220 partially or completely fills the isolating trench 600. At least part of the metal filling layer 220 extends to and covers the micro light-emitting element from the isolating trench 600. The insulating layer 500 and/or the common electrode 200 is disposed between an upper surface of the epitaxial structure layer 300 and the metal filling layer 200. The metal filling layer 200 is used to form an engagement structure, so device strength is improved in this way. The design of the metal filling layer 220 may also provide an improved heat dissipation solution.

With reference to FIG. 8, in the sixth embodiment of the disclosure, a distance is provided between the second electrode 420 and the groove 120. For instance, the metal bonding layer 421 has a distance from the groove 120, and the insulating layer 500 partially covers the surface of the driving substrate 100. In this embodiment, the bonding reliability of the device and the driving substrate 100 may be improved, but the reliability of the insulating layer 500 may be lowered.

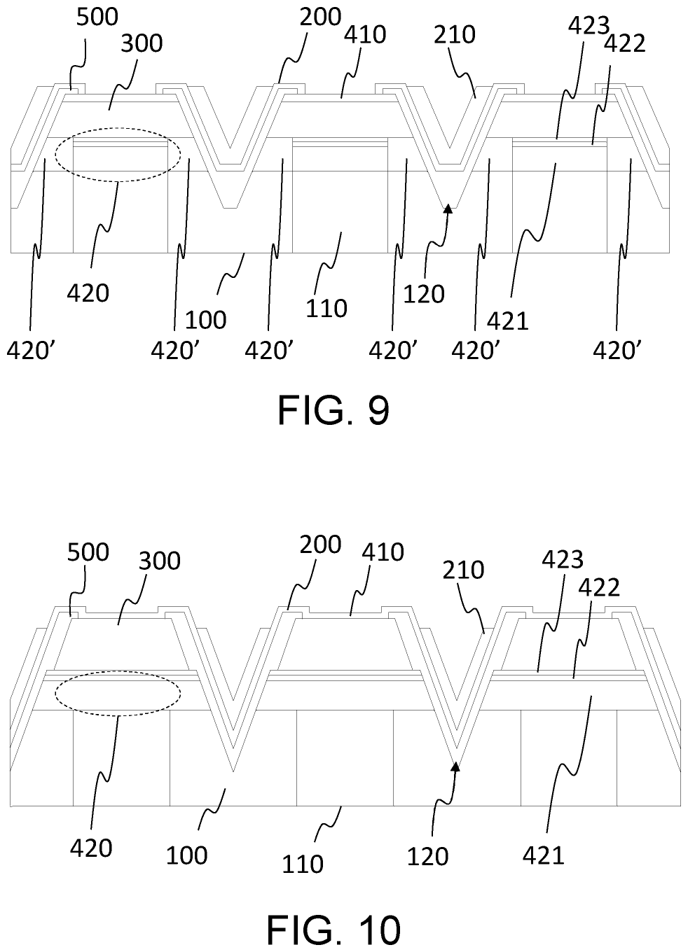

With reference to FIG. 9, in the seventh embodiment of the disclosure, the projected area of the second electrode 420 is 0.3 to 0.8 times the projected area of each of the micro light-emitting element. A supporting force provided by the second electrode 420 is decreased, and the overall device reliability is improved through matching between the insulating layer 500 and the groove 120.

In some embodiments, a support layer 420′ may not be limited to the second electrode 420. That is, the support layer 420′ is provided below the epitaxial structure layer 300, and the conductive properties are not limited. For instance, the first electrode 410 and the second electrode 420 may also be located on one side of the micro light-emitting element, and the support layer 420′ is independently provided.

With reference to FIG. 10, in the eighth embodiment of the disclosure, viewed from projection, a bottom area of the epitaxial structure layer 300 is less than a top area of the second electrode 420. The insulating layer 500 covers part of the second electrode 420, for example, covers the metal reflective layer 423, the metal barrier layer 422, or the metal bonding layer 421. Above this portion is the surface where a top surface of the second electrode 420 is exposed from the epitaxial structure layer 300.

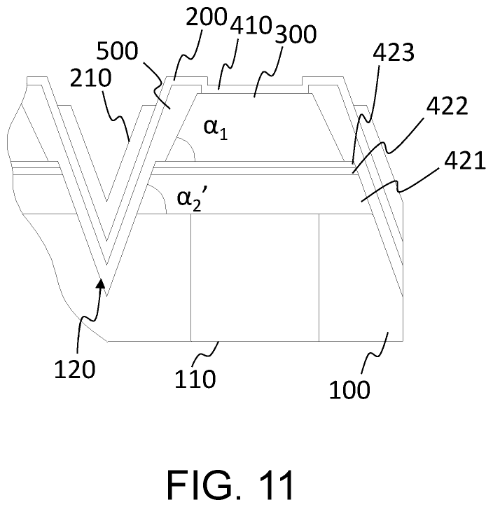

With reference to FIG. 11, in the ninth embodiment of the disclosure, in the manufacturing process of the display device, a removal process is involved, such as dry etching or wet etching. In this embodiment, the inclination angle of each sidewall is controlled through the removal process. In this embodiment, the angle between the sidewall of the epitaxial structure layer 300 and the horizontal plane is set to α₁, and the angle between the sidewall of the metal bonding layer 421 and the horizontal plane is set to α₂′. In this embodiment, α₁<α₂′, for example, 0.5α₂′≤α₁≤0.9α₂′. By setting the sidewall of the epitaxial structure layer 300 to be gentler, the coverage of the sidewall by the insulating layer 500 is improved, and the device reliability is enhanced. By setting the sidewall of the metal bonding layer 421 to be steeper, the distance between the micro light-emitting diodes is reduced. Under the requirement of ultra-small distance, the light-emitting area of the device may thereby be expanded.

Finally, it is worth noting that the foregoing embodiments are merely described to illustrate the technical means of the disclosure and should not be construed as limitations of the disclosure. Even though the foregoing embodiments are referenced to provide detailed description of the disclosure, people having ordinary skill in the art should understand that various modifications and variations can be made to the technical means in the disclosed embodiments, or equivalent replacements may be made for part or all of the technical features; nevertheless, it is intended that the modifications, variations, and replacements shall not make the nature of the technical means to depart from the scope of the technical means of the embodiments of the disclosure.

What is claimed is:

1. A display device, comprising:
a driving substrate;
a plurality of micro light-emitting elements dispersedly disposed on the driving substrate, wherein each of the plurality of micro light-emitting elements comprises an epitaxial structure layer and a first electrode and a second electrode disposed on opposite sides of the epitaxial structure layer; and
a common electrode located between the plurality of first electrodes of the plurality of micro light-emitting elements and configured to be electrically connected to the plurality of first electrodes, wherein a groove is provided on the driving substrate between the plurality of micro light-emitting elements, an insulating layer covers sidewalls of the plurality of micro light-emitting elements, and the insulating layer extends into the groove.

2. The display device according to claim 1, wherein the insulating layer is in the groove, the insulating layer contacts the groove, and a depth of the groove is greater than 100 nanometers and less than 1,000 nanometers.

3. The display device according to claim 1, wherein a cross section of the groove is V-shaped or U-shaped.

4. The display device according to claim 1, wherein a minimum distance between the plurality of micro light-emitting elements is 0.1 microns to 2 microns.

5. The display device according to claim 1, wherein the common electrode and the plurality of first electrodes are integrally formed, a material of the common electrode comprises a transparent conductive material or a metal material, and viewed from a top view, the common electrode is in a shape of a grid.

6. The display device according to claim 1, wherein at least part of the plurality of second electrodes of the plurality of micro light-emitting elements are located between the epitaxial structure layer and the driving substrate, and the plurality of micro light-emitting elements are bonded to the driving substrate through the plurality of second electrodes.

7. The display device according to claim 1, wherein viewed from a top view, a projected area of each of the plurality of second electrodes is 0.5 square micrometers to 10 square micrometers.

8. The display device according to claim 1, wherein the insulating layer in the groove is V-shaped or U-shaped.

9. The display device according to claim 1, wherein an isolating trench is provided between the plurality of micro light-emitting elements, and the groove is disposed in the isolating trench.

10. The display device according to claim 1, wherein viewed from a top view, a projected area of each of the plurality of second electrodes is 0.3 to 0.8 times or 0.8 to 1 time a projected area of each of the plurality of micro light-emitting elements.

11. The display device according to claim 1, wherein the insulating layer is disposed on the driving substrate and at least covers the first electrode of each of the plurality of micro light-emitting elements, the common electrode is located on the insulating layer, the insulating layer covers a sidewall of the groove, and the common electrode is disposed on an upper surface of the first electrode, wherein a light transmittance of the common electrode is larger than a light transmittance of the first electrode.

12. The display device according to claim 1, wherein the insulating layer extends from a sidewall of the epitaxial structure layer and a sidewall of the second electrode to a sidewall of the groove in sequence and is an insulating inorganic substance or an insulating organic substance, an angle between the sidewall of the epitaxial structure layer and a horizontal plane is α₁, an angle between the sidewall of the second electrode and the horizontal plane is α₂, and an angle between the sidewall of the groove and the horizontal plane is α₃, wherein α₁, α₂, and α₃ are 30° to 80°, and a difference value between α₁ and α₂ and a difference value between az and α₃ are not greater than 20°.

13. The display device according to claim 1, wherein the epitaxial structure layer comprises a first semiconductor layer, a second semiconductor layer, and an active layer located therebetween, the first semiconductor layer is electrically connected to the first electrode, the second semiconductor layer is electrically connected to the second electrode, the first electrode is an N-type electrode, and the second electrode is a P-type electrode.

14. The display device according to claim 9, further comprising a metal filling layer, one side of the metal filling layer partially or completely fills the isolating trench, another side of the metal filling layer covers a corresponding micro light-emitting element, and the insulating layer and/or the common electrode is disposed between an upper surface of the epitaxial structure layer and the metal filling layer.

15. The display device according to claim 1, wherein the second electrode of each of the plurality of micro light-emitting elements comprises a metal reflective layer, a metal barrier layer, or a metal bonding layer, a material of the metal bonding layer comprises gold, tin, a nickel-tin mixture, or a gold-tin mixture.

16. The display device according to claim 15, wherein the insulating layer extends from a sidewall of the epitaxial structure layer and a sidewall of the metal bonding layer to a sidewall of the groove in sequence, an angle between the sidewall of the epitaxial structure layer and a horizontal plane is α₁, an angle between the sidewall of the metal bonding layer and the horizontal plane is α₂′, and an angle between the sidewall of the groove and the horizontal plane is α₃, wherein α₁, α₂′, and α₃ are 30° to 80°, and a difference value between 1 and α₂′ and a difference value between α₂′ and α₃ are not greater than 20°.

17. The display device according to claim 16, wherein a distance between the metal bonding layers between two adjacent micro light-emitting elements is 0.1 microns to 2 microns or 2 microns to 5 microns, α₁<α₂′, and 0.5α₂′≤α1≤0.9α₂′.

18. The display device according to claim 16, wherein an edge of the metal bonding layer contacts an opening of the groove, at the contact position thereof, the sidewall of the metal bonding layer and the sidewall of the groove form a continuous surface, and a difference value between an inclination angle of the sidewall of the metal bonding layer relative to the horizontal plane and an inclination angle of the sidewall of the groove relative to the horizontal plane is not greater than 20°.

19. The display device according to claim 1, wherein the driving substrate is a metal oxide semiconductor substrate, a silicon-based liquid crystal substrate, or a thin film transistor substrate.

20. A display device, comprising:
a driving substrate;
a plurality of micro light-emitting elements dispersedly disposed on the driving substrate, wherein each of the plurality of micro light-emitting elements comprises an epitaxial structure layer and a first electrode and a second electrode disposed on opposite sides of the epitaxial structure layer; and
a common electrode located between the plurality of first electrodes of the plurality of micro light-emitting elements and configured to be electrically connected to the plurality of first electrodes, wherein an isolating trench is provided between the plurality of micro light-emitting elements, and the isolating trench extends toward the driving substrate and forms a groove on the driving substrate.
